(19) United States
(12) Patent Application Publication
(10) Pub. No.: US 2013/0275827 A1
(43) Pub. Date: Oct. 17, 2013

(54) Multi-Section Non-Binary LDPC Decoder

(71) Applicants: Chung-Li Wang, San Jose, CA (US); Lei Chen, Santa Clara, CA (US); Shaohua Yang, San Jose, CA (US); Zongwang Li, Santa Clara, CA (US); Herjen Wang, Sunnyvale, CA (US); Ngok Ying Chu, Los Altos, CA (US); Johnson Yen, Fremont, CA (US)

(72) Inventors: Chung-Li Wang, San Jose, CA (US); Lei Chen, Santa Clara, CA (US); Shaohua Yang, San Jose, CA (US); Zongwang Li, Santa Clara, CA (US); Herjen Wang, Sunnyvale, CA (US); Ngok Ying Chu, Los Altos, CA (US); Johnson Yen, Fremont, CA (US)

(73) Assignee: LSI Corporation

(21) Appl. No.: 13/445,834

(22) Filed: Apr. 12, 2012

(51) Int. Cl. H03M 13/05; G06F 11/10

(52) U.S. Cl. 714/752; 714/E11.032

(57) ABSTRACT

Various embodiments of the present invention provide systems and methods for decoding codewords in a multi-section non-binary LDPC decoder. For example, an LDPC decoder is disclosed that includes a variable node processor operable to perform variable node updates based at least in part on check node to variable node messages and to generate variable node to check node messages, and a check node processor operable to process the variable node to check node messages in groups across each of a plurality of sections of an H matrix and to generate the check node to variable node messages.

### BACKGROUND

Various data processing systems have been developed including storage systems, cellular telephone systems, and radio transmission systems. In such systems data is transferred from a sender to a receiver via some medium. For example, in a storage system, data is sent from a sender (i.e., a write function) to a receiver (i.e., a read function) via a storage medium. As information is stored and transmitted in the form of digital data, errors are introduced that, if not corrected, can corrupt the data and render the information unusable. The effectiveness of any transfer is impacted by any losses in data caused by various factors. Many types of error checking systems have been developed to detect and correct errors in digital data. For example, in perhaps the simplest system, a parity bit can be added to a group of data bits, ensuring that the group of data bits (including the parity bit) has either an even or odd number of ones. When using odd parity, as the data is prepared for storage or transmission, the number of data bits in the group that are set to one are counted, and if there is an even number of ones in the group, the parity bit is set to one to ensure that the group has an odd number of ones. If there is an odd number of ones in the group, the parity bit is set to zero to ensure that the group has an odd number of ones. After the data is retrieved from storage or received from transmission, the parity can again be checked, and if the group has an even parity, at least one error has been introduced in the data. At this simplistic level, some errors can be detected but not corrected.

The parity bit may also be used in error correction systems, including in Low Density Parity Check (LDPC) decoders. An LDPC code is a parity-based code that can be visually represented in a Tanner graph 100 as illustrated in FIG. 1. In an LDPC decoder, multiple parity checks are performed in a number of check nodes 102, 104, 106 and 108 for a group of variable nodes 110, 112, 114, 116, 118, 120, 122, and 124. The connections (or edges) between variable nodes 110-124 and check nodes 102-108 are selected as the LDPC code is designed, balancing the strength of the code against the complexity of the decoder required to execute the LDPC code as data is obtained. The number and placement of parity bits in the group are selected as the LDPC code is designed. Messages are passed between connected variable nodes 110-124 and check nodes 102-108 in an iterative process, passing beliefs about the values that should appear in variable nodes 110-124 to connected check nodes 102-108. Parity checks are performed in the check nodes 102-108 based on the messages and the results are returned to connected variable nodes 110-124 to update the beliefs if necessary. LDPC decoders may be implemented in binary or non-binary fashion. In a binary LDPC decoder, variable nodes 110-124 contain scalar values based on a group of data and parity bits that are retrieved from a storage device, received by a transmission system or obtained in some other way. Messages in the binary LDPC decoders are scalar values transmitted as plain-likelihood probability values or log-likelihood-ratio (LLR) values representing the probability that the sending variable node contains a particular value. In a non-binary LDPC decoder, variable nodes 110-124 contain symbols from a Galois Field, a finite field GF(p^{k}) that contains a finite number of elements, characterized by size p^{k} where p is a prime number and k is a positive integer. Messages in the non-binary LDPC decoders are multi-dimensional vectors, generally either plain-likelihood probability vectors or LLR vectors.

The connections between variable nodes 110-124 and check nodes 102-108 may be presented in matrix form as follows, where columns represent variable nodes, rows represent check nodes, and a non-zero element a(i,j) from the Galois Field at the intersection of a variable node column and a check node row indicates a connection between that variable node and check node and provides a permutation for messages between that variable node and check node:

$$H = [ \begin{matrix}a ( 1 , 1 ) & 0 & 0 & a ( 1 , 2 ) & 0 & a ( 1 , 3 ) & a ( 1 , 4 ) & 0 \\ 0 & a ( 2 , 1 ) & 0 & 0 & a ( 2 , 2 ) & 0 & 0 & a ( 2 , 3 ) \\ a ( 3 , 1 ) & 0 & a ( 3 , 2 ) & 0 & a ( 3 , 3 ) & a ( 3 , 4 ) & 0 & a ( 3 , 5 ) \\ 0 & a ( 4 , 1 ) & 0 & a ( 4 , 2 ) & 0 & 0 & a ( 4 , 3 ) & a ( 4 , 4 )\end{matrix} ]$$

By providing multiple check nodes 102-108 for the group of variable nodes 110-124, redundancy in error checking is provided, enabling errors to be corrected as well as detected. Each check node 102-108 performs a parity check on bits or symbols passed as messages from its neighboring (or connected) variable nodes. In the example LDPC code corresponding to the Tanner graph 100 of FIG. 1, check node 102 checks the parity of variable nodes 110, 116, 120 and 122. Values are passed back and forth between connected variable nodes 110-124 and check nodes 102-108 in an iterative process until the LDPC code converges on a value for the group of data and parity bits in the variable nodes 110-124. For example, variable node 110 passes messages to check nodes 102 and 106. Check node 102 passes messages back to variable nodes 110, 116, 120 and 122. The messages between variable nodes 110-124 and check nodes 102-108 are probabilities or beliefs, thus the LDPC decoding algorithm is also referred to as a belief propagation algorithm. Each message from a node represents the probability that a bit or symbol has a certain value based on the current value of the node and on previous messages to the node.

A message from a variable node to any particular neighboring check node is computed using any of a number of algorithms based on the current value of the variable node and the last messages to the variable node from neighboring check nodes, except that the last message from that particular check node is omitted from the calculation to prevent positive feedback. Similarly, a message from a check node to any particular neighboring variable node is computed based on the current value of the check node and the last messages to the check node from neighboring variable nodes, except that the last message from that particular variable node is omitted from the calculation to prevent positive feedback. As local decoding iterations are performed in the system, messages pass back and forth between variable nodes 110-124 and check nodes 102-108, with the values in the nodes 102-124 being adjusted based on the messages that are passed, until the values converge and stop changing or until processing is halted.

Delays may be incurred when check nodes are waiting for messages from variable nodes and when variable nodes are waiting for messages from check nodes, which may be magnified by hardware pipeline bottlenecks. Such delays are multiplied in a decoding operation by the number of local iterations performed. A need therefore remains in the art for data decoders which reduce such delays.

### BRIEF SUMMARY

The present inventions are related to systems and methods for decoding data, and more particularly to systems and methods for decoding data in a multi-section non-binary LDPC decoder. In some embodiments, an LDPC decoder is disclosed that includes a variable node processor operable to perform variable node updates based at least in part on check node to variable node messages and to generate variable node to check node messages, and a check node processor operable to process the variable node to check node messages in groups across each of a plurality of sections of an H matrix and to generate the check node to variable node messages. By dividing the H matrix associated with the LDPC decoder into sections, check node to variable node messages may be generated multiple times in a single local decoding iteration. In particular, in some embodiments, the H matrix rows are divided, and as the H matrix is processed column by column, check node calculations are performed at the divisions of the H matrix, for example at the start and middle of the H matrix.

The multi-section non-binary LDPC decoder may implement any LDPC decoding algorithm. In some embodiments, the multi-section non-binary LDPC decoder implements a min-sum based decoding algorithm, and in particular, an algorithm in which the lowest LLR values and the next lowest LLR values are identified in variable node to check node messages for each section of the H matrix, and check node to variable node messages are generated based on these values.

This summary provides only a general outline of some embodiments according to the present invention. Many other objects, features, advantages and other embodiments of the present invention will become more fully apparent from the following detailed description, the appended claims and the accompanying drawings.

### BRIEF DESCRIPTION OF THE DRAWINGS

A further understanding of the various embodiments of the present inventions may be realized by reference to the figures which are described in remaining portions of the specification. In the figures, like reference numerals may be used throughout several drawings to refer to similar components. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 depicts a Tanner graph of an example prior art LDPC code;

FIG. 2 depicts a data processing circuit including a multi-section non-binary LDPC decoder with low latency scheduling in accordance with one or more embodiments of the present inventions;

FIGS. 3A-3E depict the processing of columns of an H matrix in a multi-section non-binary LDPC decoder in accordance with one or more embodiments of the present inventions;

FIG. 4 depicts a multi-section non-binary LDPC decoder in accordance with some embodiments of the present inventions;

FIG. 5 depicts a parity calculation circuit that may be used in relation to one or more embodiments of the present inventions;

FIG. 6 depicts a select network that may be used in relation to one or more embodiments of the present inventions;

FIG. 7 depicts a select circuit that may be used in relation to one or more embodiments of the present inventions;

FIG. 8 depicts a select network that may be used in relation to one or more embodiments of the present inventions;

FIG. 9 depicts a select circuit that may be used in relation to one or more embodiments of the present inventions;

FIG. 10 depicts a flow diagram of an operation for decoding data in a multi-section non-binary LDPC decoder in accordance with one or more embodiments of the present inventions;

FIG. 11 depicts a storage system including a multi-section non-binary LDPC decoder in accordance with one or more embodiments of the present inventions; and

FIG. 12 depicts a wireless communication system including a multi-section non-binary LDPC decoder in accordance with one or more embodiments of the present inventions.

### DETAILED DESCRIPTION OF THE INVENTION

The present inventions are related to systems and methods for decoding data, and more particularly to systems and methods for decoding data in a multi-section non-binary LDPC decoder. The H matrix associated with the LDPC decoder is divided into sections enabling check node updates to be performed multiple times in a single local decoding iteration. In particular, in some embodiments, the H matrix rows are divided, and as the H matrix is processed column by column, check node calculations are performed at the divisions of the H matrix, for example at the start and middle of the H matrix. The H matrix may be divided at any location, for example in the middle of the rows or any other suitable location, and may be divided once (providing two check node updates per local iteration) or more (providing three or more check node updates per local iteration).

The multi-section non-binary LDPC decoder may implement any LDPC decoding algorithm. In some embodiments, the multi-section non-binary LDPC decoder implements a min-sum based decoding algorithm, and in particular, an algorithm in which the lowest LLR values and the next lowest LLR values are identified in messages from variable nodes to check nodes (referred to herein as V2C messages), and messages from check nodes to variable nodes (referred to herein as C2V messages) are derived from either the lowest LLR or the next lowest LLR values. The selection of the lowest LLR or the next lowest LLR value (referred to herein as the min1 and min2 values) is performed to include only extrinsic inputs, excluding prior round V2C messages from the neighboring variable node for which the C2V message is being prepared, in order to avoid positive feedback. In these embodiments, the lowest and next lowest LLR values are calculated for a portion of the H matrix, check node updates are performed based on these values, and C2V messages are performed based on the recent check node updates for that portion of the H matrix and on previously performed check node updates for other portions of the H matrix. The LDPC decoder then moves on to the next portion of the H matrix, repeating the operation for the next portion of the H matrix until all portions of the H matrix have been processed and C2V messages for the H matrix have been generated. As each group of C2V message are generated, variable node updates may be performed. Thus, check node and variable node updates may be performed multiple times per local decoding iteration, increasing message propagation during each local iteration and improving convergence speed.

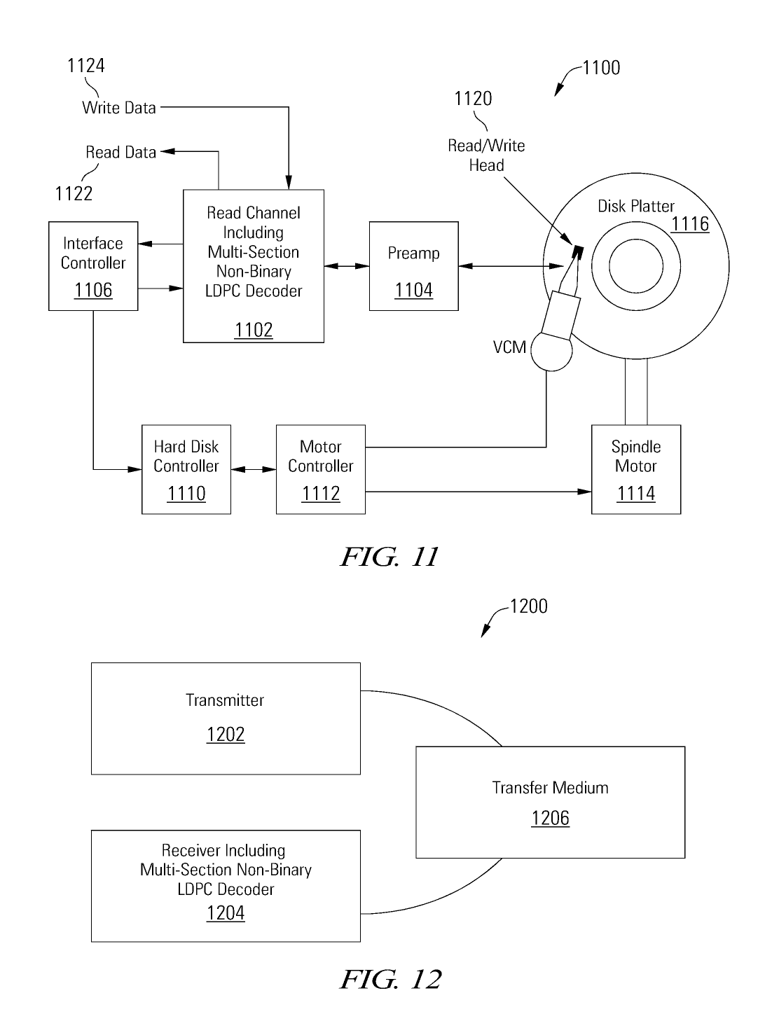

Turning to FIG. 2, a data processing circuit 200 is shown that includes a multi-section non-binary LDPC decoder 240 that is operable to decode received codewords in accordance with one or more embodiments of the present inventions. Such a data processing circuit 200 may be used, for example, in a read channel for a hard disk drive. Data processing circuit 200 includes an analog front end circuit 202 that receives an analog signal 204. Analog front end circuit 202 processes analog signal 204 and provides a processed analog signal 206 to an analog to digital converter circuit 210. Analog front end circuit 202 may include, but is not limited to, an analog filter and an amplifier circuit as are known in the art. Based upon the disclosure provided herein, one of ordinary skill in the art will recognize a variety of circuitry that may be included as part of analog front end circuit 202. In some cases, analog signal 204 is derived from a read/write head assembly (e.g., 1120, FIG. 11) that is disposed in relation to a storage medium (e.g., 1116, FIG. 11). In other cases, analog signal 204 is derived from a receiver circuit (e.g., 1204, FIG. 12) that is operable to receive a signal from a transmission medium (e.g., 1206, FIG. 12). The transmission medium may be wired or wireless. Based upon the disclosure provided herein, one of ordinary skill in the art will recognize a variety of source from which analog input 204 may be derived.

Analog to digital converter circuit 210 converts processed analog signal 206 into a corresponding series of digital samples 212. Analog to digital converter circuit 210 may be any circuit known in the art that is capable of producing digital samples corresponding to an analog input signal. Based upon the disclosure provided herein, one of ordinary skill in the art will recognize a variety of analog to digital converter circuits that may be used in relation to different embodiments of the present invention. Digital samples 212 are provided to an equalizer circuit 214. Equalizer circuit 214 applies an equalization algorithm to digital samples 212 to yield an equalized output 216. In some embodiments of the present invention, equalizer circuit 214 is a digital finite impulse response filter circuit as are known in the art. In some cases, equalizer 214 includes sufficient memory to maintain one or more codewords until a data detector circuit 220 is available for processing. It may be possible that equalized output 216 may be received directly from a storage device in, for example, a solid state storage system. In such cases, analog front end circuit 202, analog to digital converter circuit 210 and equalizer circuit 214 may be eliminated where the data is received as a digital data input.

Data detector circuit 220 is operable to apply a data detection algorithm to a received codeword or data set, and in some cases data detector circuit 220 can process two or more codewords in parallel. In some embodiments of the present invention, data detector circuit 220 is a Viterbi algorithm data detector circuit as is known in the art. In other embodiments of the present invention, data detector circuit 220 is a maximum a posteriori data detector circuit as is known in the art. Of note, the general phrases “Viterbi data detection algorithm” or “Viterbi algorithm data detector circuit” are used in their broadest sense to mean any Viterbi detection algorithm or Viterbi algorithm detector circuit or variations thereof including, but not limited to, bi-direction Viterbi detection algorithm or bi-direction Viterbi algorithm detector circuit. Also, the general phrases “maximum a posteriori data detection algorithm” or “maximum a posteriori data detector circuit” are used in their broadest sense to mean any maximum a posteriori detection algorithm or detector circuit or variations thereof including, but not limited to, simplified maximum a posteriori data detection algorithm and a max-log maximum a posteriori data detection algorithm, or corresponding detector circuits. Based upon the disclosure provided herein, one of ordinary skill in the art will recognize a variety of data detector circuits that may be used in relation to different embodiments of the present invention. Data detector circuit 220 is started based upon availability of a data set from equalizer circuit 214 or from a central memory circuit 230.

Upon completion, data detector circuit 220 provides detector output 222, which includes soft data. As used herein, the phrase “soft data” is used in its broadest sense to mean reliability data with each instance of the reliability data indicating a likelihood that a corresponding bit position or group of bit positions has been correctly detected. In some embodiments of the present invention, the soft data or reliability data is log likelihood ratio data as is known in the art. Detector output 222 is provided to a local interleaver circuit 224. Local interleaver circuit 224 is operable to shuffle sub-portions (i.e., local chunks) of the data set included as detected output 222 and provides an interleaved codeword 226 that is stored to central memory circuit 230. Interleaver circuit 224 may be any circuit known in the art that is capable of shuffling data sets to yield a re-arranged data set. Interleaved codeword 226 is stored to central memory circuit 230.

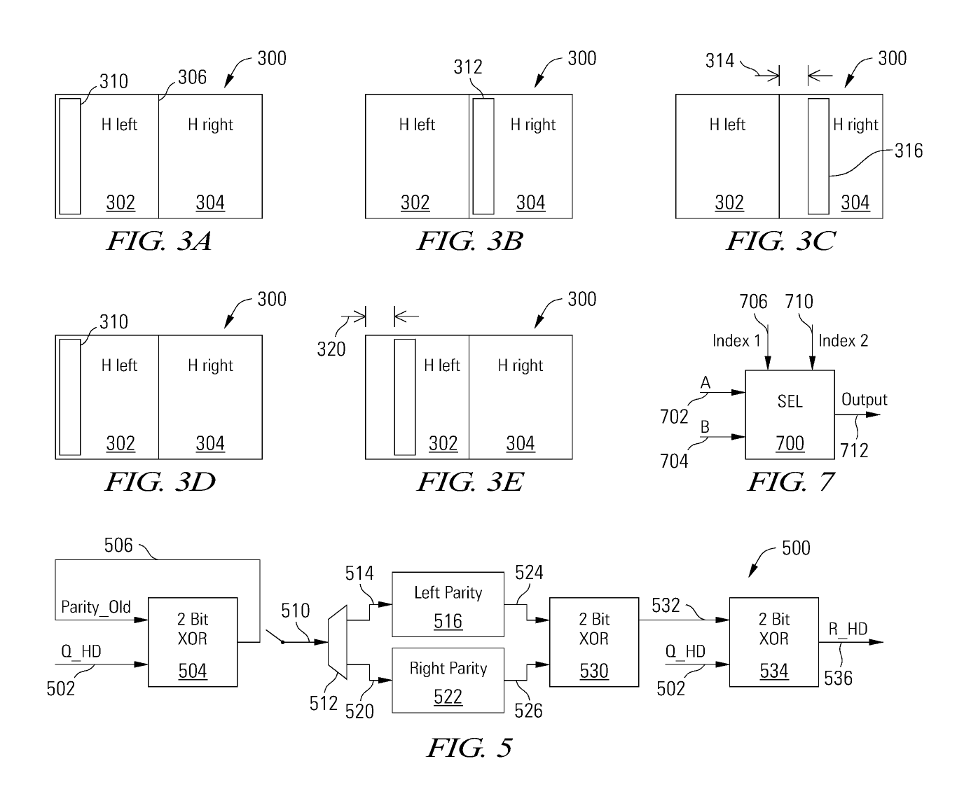

Once multi-section non-binary LDPC decoder 240 is available, a previously stored interleaved codeword 226 is accessed from central memory circuit 230 as a stored codeword 232 and globally interleaved by a global interleaver/deinterleaver circuit 234. Global interleaver/deinterleaver circuit 234 may be any circuit known in the art that is capable of globally rearranging codewords. Global interleaver/deinterleaver circuit 234 provides a decoder input 236 into multi-section non-binary LDPC decoder 240. In some embodiments of the present invention, the data decode algorithm is a non-binary non-layer min-sum based low density parity check algorithm. Based upon the disclosure provided herein, one of ordinary skill in the art will recognize other decode algorithms that may be used in relation to different embodiments of the present invention. The multi-section non-binary LDPC decoder 240 may be implemented similar to that described below in relation to FIGS. 3-9. The multi-section non-binary LDPC decoder 240 applies a data decode algorithm to decoder input 236 in a variable number of local iterations.

Where the multi-section non-binary LDPC decoder 240 fails to converge (i.e., fails to yield the originally written data set) and a number of local iterations through multi-section non-binary LDPC decoder 240 exceeds a threshold, the resulting decoded output is provided as a decoded output 242 back to central memory circuit 230 where it is stored awaiting another global iteration through data detector circuit 220 and multi-section non-binary LDPC decoder 240. Prior to storage of decoded output 242 to central memory circuit 230, decoded output 242 is globally deinterleaved to yield a globally deinterleaved output 244 that is stored to central memory circuit 230. The global deinterleaving reverses the global interleaving earlier applied to stored codeword 232 to yield decoder input 236. Once data detector circuit 220 is available, a previously stored deinterleaved output 244 is accessed from central memory circuit 230 and locally deinterleaved by a deinterleaver circuit 246. Deinterleaver circuit 246 rearranges decoder output 250 to reverse the shuffling originally performed by interleaver circuit 224. A resulting deinterleaved output 252 is provided to data detector circuit 220 where it is used to guide subsequent detection of a corresponding data set received as equalized output 216.

Alternatively, where the decoded output converges (i.e., yields the originally written data set) in the multi-section non-binary LDPC decoder 240, the resulting decoded output is provided as an output codeword 254 to a deinterleaver circuit 256. Deinterleaver circuit 256 rearranges the data to reverse both the global and local interleaving applied to the data to yield a deinterleaved output 260. Deinterleaved output 260 is provided to a hard decision output circuit 262. Hard decision output circuit 262 is operable to yield a hard decision output 264, for example based on the argminₐ of the total LLR values.

In a conventional non-binary min-sum LDPC decoder with GF(q) and with p check node rows in the parity check matrix, check node processing involves both forward and backward recursions that incur long latency since they require about q² additions and comparisons in each of p−2 basic steps. To perform both forward and backward recursions, numerous intermediate messages are stored, requiring a large memory, and messages are sorted when combining the results of forward and backward recursions. In contrast, the min-sum based decoding of non-binary LDPC codes used in some embodiments of the multi-section non-binary LDPC decoder 240 provides low-complexity decoding that does not require forward and backward recursions, sorting or dynamic programming. By including message normalization and modification of the search space, searching over various local configurations is reduced to the simple recursive processing of a single message vector.

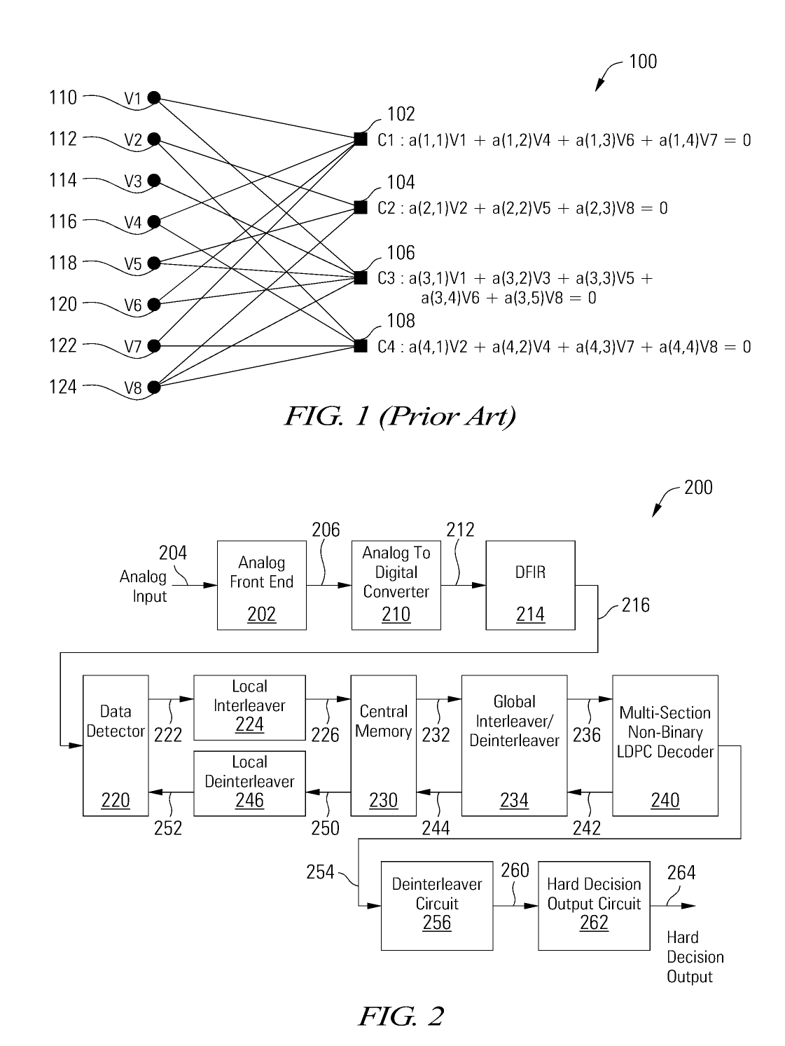

Check nodes in a min-sum based non-binary LDPC decoder receive incoming messages from connected or neighboring variable nodes and generate outgoing messages to each neighboring variable node to implement the parity check matrix for the LDPC code, an example of which is graphically illustrated in the Tanner graph of FIG. 1. Incoming messages to check nodes are also referred to herein as V2C messages, indicating that they flow from variable nodes to check nodes, and outgoing messages from check nodes are also referred to herein as C2V messages, indicating that they flow from check nodes to variable nodes. The check node uses multiple V2C messages to generate an individualized C2V message for each neighboring variable node.

Both V2C and C2V messages are vectors, each including a number of sub-messages with LLR values. Each V2C message vector from a particular variable node will contain sub-messages corresponding to each symbol in the Galois Field, with each sub-message giving the likelihood that the variable node contains that particular symbol. For example, given a Galois Field GF(q) with q elements, V2C and C2V messages will include at least q sub-messages representing the likelihood for each symbol in the field. Message normalization in the simplified min-sum decoding is performed with respect to the most likely symbol. Thus, the V2C and C2V vector format includes two parts, an identification of the most likely symbol and the LLR for the other q−1 symbols, since the most likely symbol has LLR equal to 0 after normalization.

Generally, the C2V vector message from a check node to a variable node contains the probabilities for each symbol d in the Galois Field that the destination variable node contains that symbol d, based on the prior round V2C messages from neighboring variable nodes other than the destination variable node. The inputs from neighboring variable nodes used in a check node to generate the C2V message for a particular neighboring variable node are referred to as extrinsic inputs and include the prior round V2C messages from all neighboring variable nodes except the particular neighboring variable node for which the C2V message is being prepared, in order to avoid positive feedback. The check node thus prepares a different C2V message for each neighboring variable node, using the different set of extrinsic inputs for each message based on the destination variable node.

In the simplified min-sum based decoding applied in some embodiments of the multi-section non-binary LDPC decoder 240 disclosed herein, the check nodes calculate the lowest sub-message min₁(d), the index idx(d) of min₁(d), and the next lowest sub-message min₂(d), or minimum of all sub-messages excluding min₁(d), for each nonzero symbol din the Galois Field based on all extrinsic V2C messages from neighboring variable nodes. In other words, the sub-messages for a particular symbol d are gathered from messages from all extrinsic inputs, and the min₁(d), idx(d) and min₂(d) is calculated based on the gathered sub-messages for that symbol d. For a Galois Field with q symbols, the check node will calculate the min₁(d), idx(d) and min₂(d) sub-message for each of the q−1 non-zero symbols in the field except the most likely symbol. The min₁(d), idx(d) and min₂(d) values are stored in a memory for use in calculating the C2V message, requiring much less memory than the traditional non-binary LDPC check node processor that stores each intermediate forward and backward message.

When applied to multi-section LDPC decoding, the min₁(d), idx(d) and min₂(d) calculations are performed for each portion of the H matrix, for example across the left side and right side of an H matrix divided into two sections. This is illustrated in FIGS. 3A-3E, which depict the processing of columns of an H matrix in a multi-section non-binary LDPC decoder. In this example, the H matrix 300 is divided into a left side 302 and a right side 304, divided at a middle point 306, with the V2C messages processed in groups corresponding with the left side 302 and the right side 304. (Again, the H matrix may be divided in other ways and into other numbers of portions.) Turning to FIG. 3A, the H matrix 300 is processed column by column, starting, for example, with the leftmost column 310. This column-wise processing includes identifying min₁(d), idx(d) and min₂(d) values in V2C messages for each non-zero value in GF(q) and computing parity symbols across the left side 302. Once each column (e.g., 310) of the left side 302 of the H matrix 300 has been processed, the resulting min₁(d), idx(d) and min₂(d) values (which may be referred to as min_{1—}l(d), idx_l(d) and min_{2—}l(d)) and parity symbols are stored.

Turning to FIG. 3B, the right side 304 is processed, starting, for example, with the leftmost column 312 of the right side 304. This column-wise processing includes identifying min₁(d), idx(d) and min₂(d) values for each non-zero value in GF(q) and computing parity symbols across the right side 304. Once each column (e.g., 312) of the right side 304 of the H matrix 300 has been processed, the resulting min₁(d), idx(d) and min₂(d) values (which may be referred to as min_{1—}r(d), idx_r(d) and min_{2—}r(d)) and parity symbols are stored. The same working registers for identifying min₁(d), idx(d) and min₂(d) may be used for the left side 302 and right side 304 of the H matrix 300, with the registers being reset to 0 or to other default values when transitioning from the left side 302 to the right side 304 or vice versa.

Turning to FIG. 3C, after an update delay 314 while processing the right side 304, check node updates and C2V message calculation may be performed. Check node updates are performed and C2V messages are generated based on the newly calculated min_{1—}l(d), idx_l(d) and min_{2—}l(d) values and parity symbol values for the left side 302 and on previously calculated min_{1—}r(d), idx_r(d) and min_{2—}r(d) values for the right side 304. These updates may be performed even while continuing to process columns (e.g., 316) of the right side 304. The update delay 314 is the delay before the newly identified min_{1—}l(d), idx_l(d) and min_{2—}l(d) values and parity symbol values for the left side 302 are available, which may take some clock cycles. Until the timing point at which the update delay 314 has elapsed, the previously identified min_{1—}l(d), idx_l(d) and min_{2—}l(d) values and parity symbol values for the left side 302 continue to be used.

Turning to FIG. 3D, after the right side 304 of the H matrix 300 has been processed, the left side 302 may again be processed as disclosed above with respect to FIG. 3A. In some embodiments, this would take place in another local decoding iteration in the LDPC decoder, with the entire H matrix 300 being processed once per local decoding iteration.

Turning to FIG. 3E, after an update delay 320 while processing the left side 302, check node updates and C2V message calculation may again be performed. Check node updates are performed and C2V messages are generated based on the newly calculated min_{1—}r(d), idx_r(d) and min_{2—}r(d) values and parity symbol values for the right side 304 and on previously calculated min_{1—}l(d), idx_l(d) and min_{2—}l(d) values and parity symbol values for the left side 302. The update delay 320 is the delay before the newly identified min_{1—}r(d), idx_r(d) and min_{2—}r(d) values and parity symbol values for the right side 304 are available. Until the timing point at which the update delay 320 has elapsed, the previously identified min_{1—}r(d), idx_r(d) and min_{2—}r(d) values and parity symbol values for the right side 304 continue to be used.

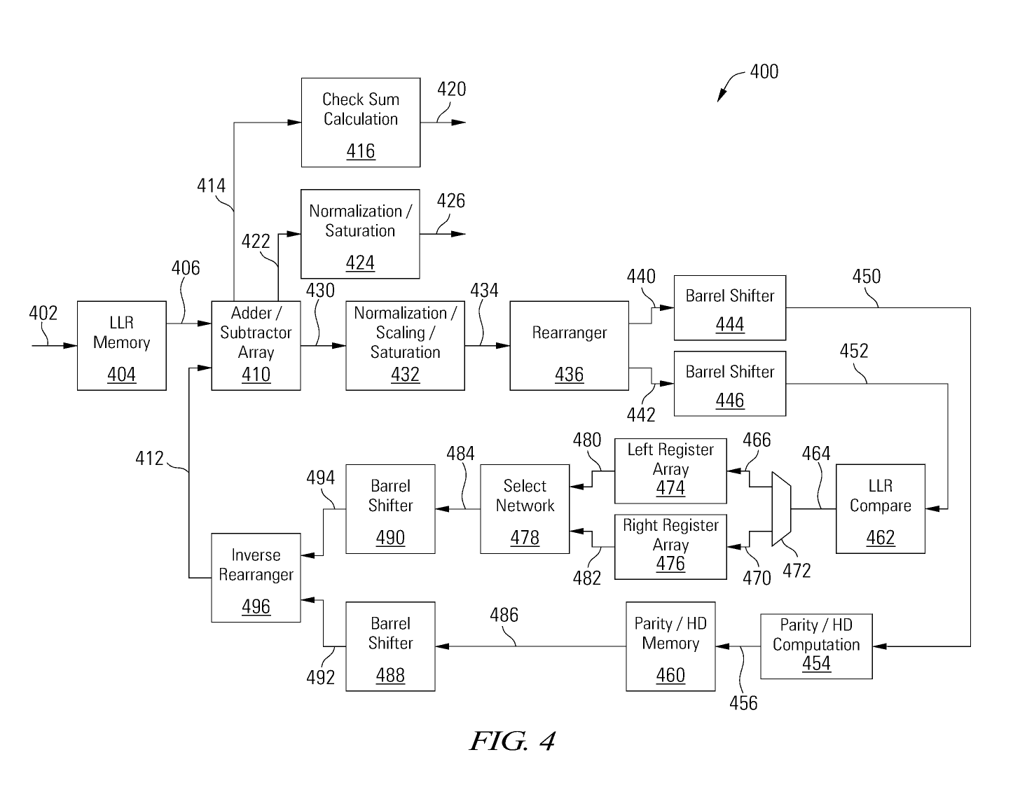

Turning to FIG. 4, a multi-section non-binary LDPC decoder 400 is shown in accordance with various embodiments of the present inventions, applying the simplified min-sum based decoding disclosed above. Again, it is important to note that the multi-section non-binary LDPC decoder 400 is not limited to use with min-sum based decoding or to any particular LDPC decoding algorithm. The multi-section non-binary LDPC decoder 400 may be used, for example, in place of the multi-section non-binary LDPC decoder 240 of FIG. 2. A simplified min-sum based LDPC decoder may be adapted to multi-section decoding, for example the simplified min-sum based LDPC disclosed in U.S. patent application Ser. No. 13/180,495 for a “Min-Sum Based Non-Binary LDPC Decoder”, filed Jul. 11, 2011, which is incorporated by reference herein for all purposes.

The multi-section non-binary LDPC decoder 400 is provided with LLR values from an input channel 402, which may be stored in an LLR memory 404. Stored values 406 are provided to an adder/subtractor array 410, also referred to as a variable node processor or variable node unit (VNU) or as a portion of a VNU. The adder/subtractor array 406 updates the perceived value of symbols based on the value from input channel 402 and on C2V message vectors 412. The adder/subtractor array 410 yields an external LLR output 414 to a check sum calculation circuit 416, which generates a parity check output 420. For example, check sum calculation circuit 416 may include multiplexers and XOR circuits to calculate parity check equation ν·H^{T}=0 over GF(q), where νεGF(q)^{N}, and where ν is a codeword vector and H^{T} is the transform of the H matrix for the LDPC decoder. The adder/subtractor array 410 also yields an external LLR output 422 to a normalization/saturation circuit 424, which generates a hard decision output 426.

The adder/subtractor array 410 performs an update function, adding C2V message vectors 412 to symbol values, and generates V2C message vectors 430 setting forth the updated likelihood or LLR value for each element in the Galois Field for each symbol in the data set. The V2C message vectors 430 are provided to a normalization/scaling/saturation circuit 432 which scales the LLR values and converts them to normalized V2C message vectors 434. The normalized V2C message vectors 434 contain a hard decision (an indication of the most likely GF element), and LLR values for the remaining GF elements for each symbol, each normalized to the hard decision. For example, in a GF(4) LDPC decoder, the normalization/scaling/saturation circuit 432 takes the four LLR data values for each symbol, identifies the highest LLR data value of the four values, and normalizes the four LLR data values to the value of the highest LLR data value. An example of this is shown using the following example symbol:

| Hard Decision | 00 | 01 | 10 | 11 |
|---|---|---|---|---|
| LLR Data Value | 10 | 15 | 22 | 6 |

In this example, the normalization/scaling/saturation circuit 432 selects the LLR data value ‘22’ corresponding to the hard decision ‘10’. Next, the LLR data values corresponding to hard decision values ‘00’, ‘01’, ‘10’ and ‘11’ are normalized to LLR data value ‘22’ by subtracting ‘22’ from each of the LLR data values to yield the following normalized symbol:

| Hard Decision | 00 | 01 | 10 | 11 |
|---|---|---|---|---|
| Normalized LLR Data Value | −12 | −7 | 0 | −16 |

The LLR values may also be scaled in normalization/scaling/saturation circuit 432, multiplying each of the normalized LLR data values by a scaling factor. The scaling factor may be user programmable. As an example, with a scaling factor of 0.5, the normalized V2C message vectors 434 might include the following scaled symbol based on the current example:

| Hard Decision | 00 | 01 | 10 | 11 |
|---|---|---|---|---|
| Normalized LLR Data Value | −6 | −4 | 0 | −8 |

The V2C message vectors 434 are provided to a rearranger 436 which shuffles messages on the boundaries at message edges, randomizing noise and breaking dependencies between messages, and yielding rearranged V2C message vectors 440 and 442. The rearranged V2C message vectors 440 and 442 are provided to barrel shifters 444 and 446, respectively, which shift the symbol values in the rearranged V2C message vectors 440 and 442 to generate the next circulant sub-matrix, yielding shifted LLR values 450 and 452. In some embodiments, the code structure of the codeword provided at input channel 402 has a code structure matrix of the following form:

$$[ \begin{matrix}{P}_{1 , 1} & {P}_{1 , 2} & … & {P}_{1 , j} & … & {P}_{1 , L} \\ {P}_{2 , 1} & {P}_{2 , 2} & … & {P}_{2 , j} & … & {P}_{2 , L} \\ {P}_{3 , 1} & {P}_{2 , 2} & … & {P}_{3 , j} & … & {P}_{3 , L} \\ {R}_{1} & {R}_{2} & … & {R}_{j} & … & {R}_{L}\end{matrix} ]$$

$${R}_{j} = [ \begin{matrix}{q}_{{p}_{1} \times {p}_{1}}^{j + 0} & {q}_{{p}_{1} \times {p}_{1}}^{j + 1} & … & {q}_{{p}_{1} \times {p}_{1}}^{j + k}\end{matrix} ]$$

where each of P_{I,J} are p×p circulants with weight 1, or permutations of the identity matrix, and the circulant size L is the row weight. The following is an example of a p×p circulant representative of P_{I,J}:

$${P}_{I , J} = [ \begin{matrix}0 & α & 0 & … & 0 \\ 0 & 0 & α & … & 0 \\ ⋮ & ⋮ & ⋮ & ⋱ & ⋮ \\ 0 & 0 & 0 & … & α \\ α & 0 & 0 & … & 0\end{matrix} ]$$

The barrel shifters 444 and 446 are operable to shift the currently received circulant to an identity matrix. Such an identity matrix may be as follows:

$${P}_{I , J} = [ \begin{matrix}α & 0 & 0 & … & 0 \\ 0 & α & 0 & … & 0 \\ ⋮ & ⋮ & ⋮ & ⋱ & ⋮ \\ 0 & 0 & 0 & … & 0 \\ 0 & 0 & 0 & … & α\end{matrix} ]$$

Barrel shifter 444 provides shifted output 450, which contains the magnitude and sign of the hard decision HD. Barrel shifter 446 provides shifted output 452, which contains the magnitudes of the remaining LLR values, normalized to the hard decision HD. The shifted output 450 is provided to a parity/HD computation circuit 454 which calculates the accumulative sign for the hard decisions in shifted output 450, storing the resulting sign values 456 for each non-zero element of the portion of the H matrix being processed, and the hard decisions, in a parity/HD memory 460.

The shifted output 452 is provided to an LLR comparison circuit 462, which calculates the first minimum LLR value or sub-message min₁(d), (i.e., the lowest LLR value), the index idx(d) of min₁(d) (i.e., the location in the row corresponding to the first minimum LLR data value), and the second minimum LLR value or sub-message min₂(d), (i.e., the second lowest LLR value) or minimum of all sub-messages excluding min₁(d), for each nonzero symbol din the Galois Field based on all extrinsic V2C messages in the portion of the H matrix being processed. In other words, the sub-messages for a particular symbol d are gathered from messages from all extrinsic inputs for the portion of the H matrix being processed, and the min₁(d), idx(d) and min₂(d) is calculated based on the gathered sub-messages for that symbol d. For a Galois Field with q symbols, the check node will calculate the min₁(d), idx(d) and min₂(d) sub-message for each of the q−1 non-zero symbols in the field except the most likely symbol, the hard decision HD.

Again, columns in the H matrix represent variable nodes, rows represent check nodes, and non-zero values in the H matrix indicate a connection between the column and row at the non-zero intersection. In general, the multi-section min-sum based decoding algorithm identifies the lowest extrinsic input value to a check node from each connected variable node in the portion or section of the H matrix being processed, for each non-zero element of the Galois Field except the most likely symbol or HD, by finding the lowest and next lowest LLR value for each non-zero Galois Field element other than the HD among the connected variable nodes (or non-zero row values) in the portion of the H matrix being processed.

Because the H matrix is divided into multiple portions or sections, for example a left side and a right side, the min₁(d), idx(d) and min₂(d) values are alternately calculated for each side of the H matrix so that check node updates can be performed twice per iteration, once early in processing of the left side based on newly identified min_{1—}r(d), idx_r(d) and min_{2—}r(d) values for the right side and on previously identified min_{1—}l(d), idx_l(d) and min_{2—}l(d) values for the left side, and again early in processing of the right side based on newly identified min_{1—}l(d), idx_l(d) and min_{2—}l(d) values for the left side and on previously identified min_{1—}r(d), idx_r(d) and min_{2—}r(d) values for the right side.

Identification of the lowest and next lowest LLR value is performed in the LLR comparison circuit 462, with the results 464 (in a two-section LDPC decoder) divided into left side results 466 and right side results 470, for example by switch 472. The left side results 466 (or min_{1—}l(d), idx_l(d) and min_{2—}l(d) values) are stored in a left register array 474. The right side results 470 (or min_{1—}r(d), idx_r(d) and min_{2—}r(d) values) are stored in a right register array 476. The register arrays 474 and 476 for a two-section LDPC decoder store left and right sets of min₁(d), idx(d) and min₂(d) values for each non-zero GF element other than the HD at each check node or row of the H matrix. In some embodiments of a GF(4) decoder, there is a set of three min₁(d), idx(d) and min₂(d) registers for the left side of the H matrix and three min₁(d), idx(d) and min₂(d) registers for the right side of the H matrix, for each check node or row of the H matrix. With a code structure matrix having three rows, the left register array 474 and right register array 476 would each store three sets of first minimum LLR data value, second minimum LLR data value, index value as shown in the example below:

| | |
|---|---|
| Row 1 | First Minimum LLR Value |
| | Second Minimum LLR Value |
| | Index Value |
| Row 2 | First Minimum LLR Value |
| | Second Minimum LLR Value |
| | Index Value |
| Row 3 | First Minimum LLR Value |
| | Second Minimum LLR Value |
| | Index Value |

Before starting the LLR compare process in the LLR comparison circuit 462 for each side of the H matrix, the left register array 474 or right register array 476 is reset to an initial value, for example zero. As the first non-zero LLR values are received when processing each column in that side of the H matrix, they overwrite the initial zero values. As processing of each column in that side of the H matrix continues, if the LLR value for a non-zero GF element is lower than the value in the min₁(d) register, the min₁(d) register is updated with the LLR value for the non-zero GF element, the previous value in the min₁(d) register is copied into the min₂(d) register as the next lowest value, and the idx(d) register is updated with the index of the current working column. If the LLR value for the non-zero GF element was greater than the value in the min₁(d) register but lower than the value in the min₂(d) register, the min₂(d) register is updated with the LLR value for the GF element. As each column is processed, this LLR comparison is performed for the sets of min₁(d), idx(d) and min₂(d) registers for each check node or row in the column.

At the end of processing a section of the H matrix in the LLR comparison circuit 462, a select network 478 performs a check node update based on the stored left side results 480 (or min_{1—}l(d), idx_l(d) and min_{2—}l(d) values) stored in the left register array 474 and on the stored right side results 482 (or min_{1—}r(d), idx_r(d) and min_{2—}r(d) values) stored in the right register array 476. The check node updates are based on newly identified values for one side (e.g., 474) and previously identified values for the other side (e.g., 476), with the side having the newly identified values alternating between the left side and the right side as the H matrix is processed, as disclosed above with respect to FIGS. 3A-3E. For example, once all columns in the left side (e.g., 302) of the H matrix have been processed, and after an update delay (e.g., 314), the check node update is performed based on the new min_{1—}l(d), idx_l(d) and min_{2—}l(d) values stored in the left register array 474 and on the old min_{1—}r(d), idx_r(d) and min_{2—}r(d) values stored in the right register array 476. The right side (e.g., 304) of the H matrix is then processed as disclosed above, first resetting the right register array 476. When the right side of the H matrix has been processed, and after an update delay (e.g., 320), another check node update may be performed based on the old min_{1—}l(d), idx_l(d) and min_{2—}l(d) values stored in the left register array 474 and on the new min_{1—}r(d), idx_r(d) and min_{2—}r(d) values stored in the right register array 476.

The LLR comparison circuit 462, register arrays 474 and 476, and select network 478 may be collectively referred to as a check node processor or check node unit (CNU). The simplified min-sum based CNU disclosed herein and which may be used in some embodiments of a multi-section non-binary LDPC decoder is also referred to as a compression circuit. The select network 478 selects as output 484 either the min₁(d) or min₂(d) to be used in the C2V message 412 such that only extrinsic values are selected. If the current column index is equal to the index of the minimum value, meaning that the C2V message is being prepared for a variable node that provided the min₁(d) value, then the value to be used in the C2V message 412 is the second minimum value min₂(d). Otherwise, the value to be used in the C2V message 412 is the first minimum value min₁(d). The select network 478 also considers the min₁(d) or min₂(d) values from both sides of the H matrix, selecting the lowest LLR value from them both. When processing the left side of the H matrix, this may be accomplished according to the equation:

sel[d]=min(((circ_idx==idx_{—}l[d])?min_{2—}l[d]:min_{1—}l[d]),min_{1—}r[d]) (Eq 1)

where d is the GF element index, where circ_idx is the index of the working column, that is, the index of the variable node for which the C2V message is being generated, and where idx 1 is the column index of the min_{1—}l(d) value. For a GF(4) decoder, d=0, 1, 2. The outer min statement selects the extrinsic minimum LLR value from either the left or the right side. Because in this instance the left side of the H matrix is being processed, the index circ_idx of the working column is in the left side, and min_{1—}r(d) cannot have come from the variable node at the working column and is therefore from an extrinsic input. In contrast, the min_{1—}l(d) may have come from the variable node at the working column, so the idx_l(d) is compared with the working column index circ_idx. If they are equal, then the min_{1—}l(d) is not an extrinsic input and the min_{2—}l(d) value is used rather than min_{1—}l(d). Notably, the equation may be adapted to select from among more than two portions if the H matrix is further divided.

When processing the right side of the H matrix, the select network 478 selects the lowest LLR value from both sides of the H matrix according to the equation:

sel[d]=min(min_{1—}l[d],((circ_idx==idx_{—}r[d])?min_{2—}r[d]:min_{1—}r[d])) (Eq 2)

where idx_r is the column index of the min_{1—}r(d) value for the right side. Again, the outer min statement selects the extrinsic minimum LLR value from either the left or the right side. Because in this instance the right side of the H matrix is being processed, the index circ_idx of the working column is in the right side, and min_{1—}l(d) cannot have come from the variable node at the working column and is therefore from an extrinsic input. In contrast, the min_{1—}r(d) may have come from the variable node at the working column, so the idx_r(d) is compared with the working column index circ_idx. If they are equal, then the min_{1—}r(d) is not an extrinsic input and the min_{2—}r(d) value is used rather than min_{1—}r(d).

The R values or LLR values for each element of the Galois Field making up a portion of the C2V message vectors 412 are calculated based on the sel[d] in the select network 478, for example according to equations 3-5 in a GF(4) LDPC decoder:

R[0]=min(sel[0],sel[1]+sel[2]) (Eq 3)

R[1]=min(sel[1],sel[0]+sel[2]) (Eq 4)

R[2]=min(sel[2],sel[0]+sel[1]) (Eq 5)

For an LDPC decoder with more Galois Field elements, there would be additional equations for the extra R terms.

The hard decision HD and sign to be used in the C2V message 412 is provided at the output 486 of parity/HD memory 460, with the sign or parity calculated as the XOR of the cumulative sign and the current sign of the symbol. The R HD value to be used as the hard decision value in the C2V message vectors 412 may be calculated according to equation 6:

R_{HD}=sgn_{—}l XOR sgn_{—}r XOR Q_HD (Eq 6)

where sgn_l and sgn_r are sign or parity values for each portion of the H matrix, and Q_HD is the previous hard decision in the V2C message vectors 440, combined in XOR operations. Again, if the H matrix were divided into more than two portions, equation 6 would have additional sign terms. The hardware used to implement equations 1-6 may be shared and used for each portion of the H matrix, or may be duplicated for each portion of the H matrix.

The output 486 of parity/HD memory 460 and the output 484 of select network 478 are provided to barrel shifters 488 and 490, respectively, which shift the hard decisions and their signs in output 486 and the C2V message values in output 484 to yield shifted hard decisions and signs 492 and shifted C2V message values 494, respectively, shifting between circulant sub-matrices. The shifted C2V message values 494 and shifted hard decisions and signs 492 are combined and processed in an inverse rearranger 496 which combines the inputs 492 and 494 and which reverses the effect of rearranger 436 to yield C2V message vectors 412. The combining portion of inverse rearranger 496 is also referred to herein as a data decompression circuit, and reassembles rows to yield an approximation of the original data.

Turning to FIG. 5, a parity calculation circuit 500 is depicted that may be used in place of parity/HD computation circuit 454 in one or more embodiments of the present inventions. The parity calculation circuit 500 processes the symbol portion of each message vector (e.g., in shifted LLR values 450) from each neighboring variable node. Each of the most likely symbols or HD values 502 (for example from the shifted LLR values 450) is provided to an XOR circuit 504 where they are recursively XORed together, XORing each HD value 502 with the previous HD value 506. In the case of an LDPC decoder using two-bit symbols, the XOR circuit 504 is a two-bit XOR. The intermediate results 510 are separated according to the division in the H matrix, for example by a multiplexer 512. For example, in an LDPC decoder with two sections, the left side intermediate results 514 are stored in a left side parity register 516, and the right side intermediate results 520 are stored in a right side parity register 522. The parity values stored in the left side parity register 516 are cumulative parity values for the left side of the H matrix (or sgn_l values of Equation 6), and the parity values stored in the right side parity register 522 are cumulative parity values for the right side of the H matrix (or sgn_r values of Equation 6). The stored left side results 524 and the stored right side results 526 are combined in an XOR circuit 530 to yield a combined cumulative parity value 532, which is combined with the HD values 502 in an XOR circuit 534 to complete the operation of Equation 6, yielding R HD values 536 to be used as the hard decision values in the C2V message vectors 412.

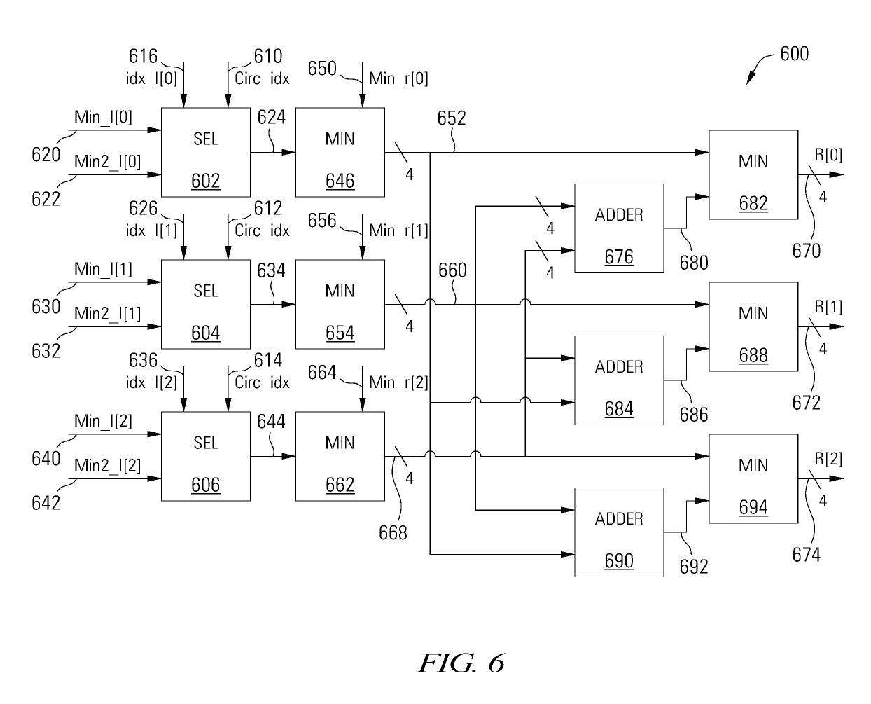

Turning to FIG. 6, a select network 600 is depicted that may be used in place of the select network 478 of FIG. 4, given a GF(4) decoder. The select network 600 is configured in FIG. 6 to implement Equations 1 and 3-5 above, as it is used when processing the left side of an H matrix. The select network 600 may also be configured to implement Equations 2 and 3-5 when processing the right side of an H matrix, for example using a multiplexer to provide the appropriate inputs to the components of the select network 600. The select network 600 processes inputs representing the lowest and next lowest LLR values for each of the Galois Field elements other than the most likely symbol, combining the results from the multiple sections of the H matrix. For the GF(4) embodiment of FIG. 6, the select network 600 therefore processes three sets of lowest and next lowest LLR values from each of two sides of the H matrix. As disclosed above, the lowest and next lowest LLR values for a particular Galois Field element are selected from all sub-messages for that Galois Field element from the neighboring variable nodes in a given section of the H matrix, and an index value is preserved identifying the variable node from which the minimum was selected. (The next lowest LLR will be from a different variable node.) The select network 600 participates in generating C2V messages for each neighboring variable node, and thus a variable k cycles through each of the neighboring variable nodes to generate the C2V message for each.

The selection is performed in a group of three selector circuits 602, 604 and 606, controlled by index inputs 610, 612 and 614 cycling through the variable nodes or columns in the H matrix. Each of the three selector circuits 602, 604 and 606 may be a selector circuit 700 as illustrated in FIG. 7, with a pair of inputs 702 and 704 (A and B, respectively), and two index inputs 706 and 710. The selector circuit 700 selects either the first input 702 or the second input 704 as the output 712, according to the equation:

Output=(index1==index2)?B:A (Eq 7)

where the output 712 is equal to the second input 704 or input B if the indexes 706 and 710 are equal, otherwise output 712 is equal to the first input 702 or input A.

The first selector circuit 602 has an idx_l[0] input 616, index input 610, min_{1—}l(0) input 620 and min_{2—}l(0) input 622, yielding output 624 according to Equation 7. The second selector circuit 604 has an idx_l[1] input 626, index input 612, min_{1—}l(1) input 630 and min_{2—}l(1) input 632, yielding output 634. The third selector circuit 606 has an idx_l[2] input 636, index input 614, min_{1—}l(2) input 640 and min_{2—}l(2) input 642, yielding output 644. Outputs 624, 634 and 644 thus provide the lowest LLR input from the left side of the H matrix, unless the index inputs (e.g., 616 and 610) are equal, indicating that the lowest LLR value is from the same variable node for which the C2V message is being generated, in which case the next lowest LLR input from another variable node is provided. Thus, only extrinsic inputs are used in the generation of a C2V message, avoiding V2C messages from current variable nodes.

Output 624 is provided to a minimum selector circuit 646, along with the min_{1—}r(0) value 650, which selects the lower of the value at output 624 and the min_{1—}r(0) value 650, yielding output 652 (or sel[0] according to Equation 1). Output 634 is provided to a minimum selector circuit 654, along with the min_{1—}r(1) value 656, which selects the lower of the value at output 634 and the min_{1—}r(1) value 656, yielding output 660 (or sel[1] according to Equation 1). Output 644 is provided to a minimum selector circuit 662, along with the min_{1—}r(2) value 664, which selects the lower of the value at output 644 and the min_{1—}r(2) value 664, yielding output 668 (or sel[2] according to Equation 1).

The R values 670, 672 and 674 are generated by the select network 600 according to equations 3-5 based on the sel[k] values 652, 660 and 668. The sel[1] value 660 and sel[2] value 668 are added in adder 676 to yield sum output 680. A minimum selector circuit 682 yields as R[0] output 670 the lesser of sel[0] value 652 and sum output 680. The sel[0] value 652 and sel[2] value 668 are added in adder 684 to yield sum output 686. A minimum selector circuit 688 yields as R[1] output 672 the lesser of sel[1] value 660 and sum output 686. The sel[0] value 652 and sel[1] value 660 are added in adder 690 to yield sum output 692. A minimum selector circuit 694 yields as R[2] output 674 the lesser of sel[2] value 668 and sum output 692.

In some embodiments, the C2V message vectors 412 are formed with the output 484 of the select network 478 (which may include R values, e.g., 670, 672 and 674) as LLR values and with the XOR of the parity symbol and the hard decision in the output 486 of the parity/HD memory 460 as the new hard decision.

When sharing a single select network 600 when processing the left and right sides of an H matrix, the left and right inputs to the select network 600 can be swapped. This may be accomplished in some embodiments using multiplexers to supply the appropriate inputs with left side values or right side values.

Turning to FIG. 8, another embodiment of a select network 800 is depicted that may be used in place of the select network 478 of FIG. 4, given a GF(4) decoder. In this embodiment, the select network 800 receives inputs for both the left and right sections of an H matrix, combining the inputs in check node updates performed while processing the left and right sections. The select network 800 thus implements Equations 1-5 above. The select network 800 is adapted for use with a GF(4) decoder in which the H matrix is divided into a left section and a right section. The select network 800 may be adapted in other embodiments for other Galois Field sizes and for other numbers of sections in an H matrix.

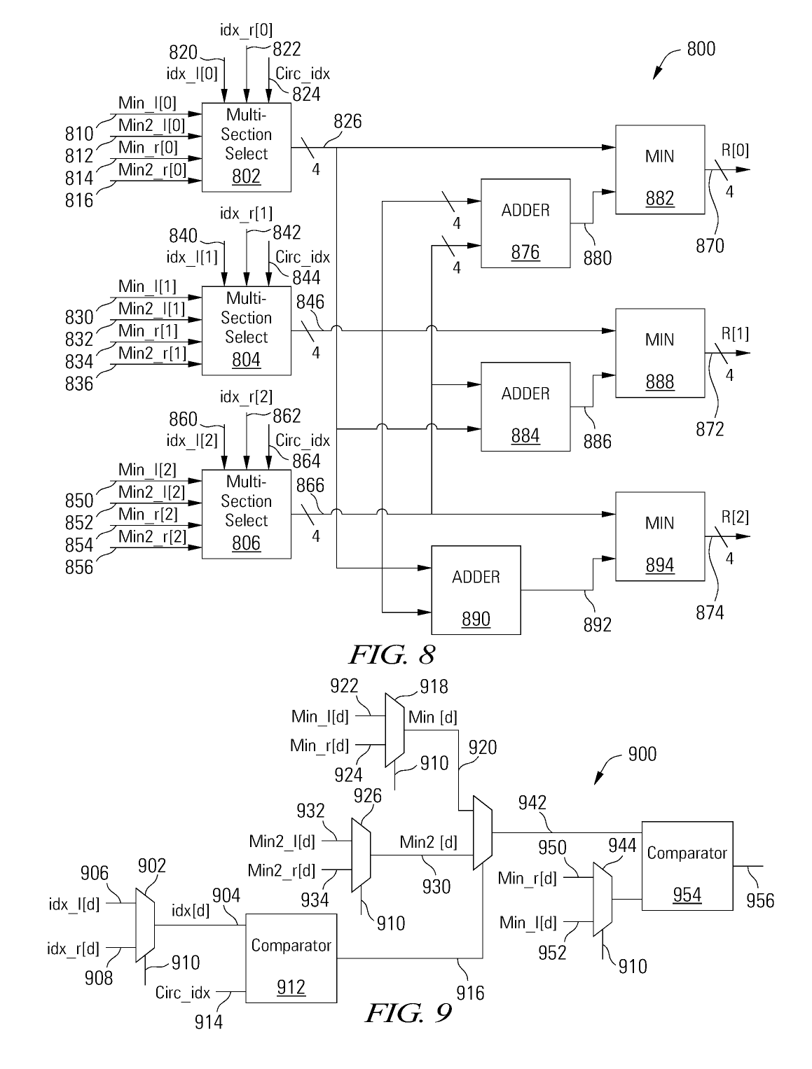

The selection is performed in a group of three selector circuits 802, 804 and 806, controlled by index inputs 610, 612 and 614 cycling through the variable nodes or columns in the H matrix. Each of the three selector circuits 802, 804 and 806 may be a multi-selection selector circuit 900 as illustrated in FIG. 9, which implements Equations 1 and 2. As shown in FIG. 9, the multi-selection selector circuit 900 includes a multiplexer 902 which selects as output 904 either idx_l(d) at left index input 906 or idx_r(d) at right index input 908, based on a section selector 910 which indicates whether the left side or right side of the H matrix is being processed. A comparator 912 compares the working column index circ_idx 914 with the index of the min₁(d) value for the side of the H matrix being processed, yielding an output 916 which indicates whether the lowest LLR value was provided by the variable node for which the C2V message is being generated. A multiplexer 918 yields min₁(d) at output 920, selecting either min_{1—}l(d) from the left section at a first input 922 or min_{1—}r(d) from the right section at a second input 924, based on the section selector 910. A multiplexer 926 yields min₂(d) at output 930, selecting either min_{2—}l(d) from the left section at a first input 932 or min_{2—}r(d) from the right section at a second input 934, based on the section selector 910. A multiplexer 940 selects either min₁(d) from output 920 or min₂(d) from output 930 based on the output 916 of comparator 912, yielding min₂(d) at output 942 if circ_idx 914 is equal to the idx(d) of the current variable node identified at output 904 of multiplexer 902, otherwise yielding min₁(d) at output 942. A multiplexer 944 yields as output 946 either min_{1—}r(d) at input 950 or min_{1—}l(d) at input 952, depending on the section selector 910. Note that multiplexer 944 is configured to select the opposite side from that selected by multiplexers 902, 918 and 926. A comparator 954 selects either the extrinsic value of min(d) at output 942 from the side of the H matrix being processed or the min(d) at output 946 from the side of the H matrix not currently being processed, yielding sel[k] at output 956.

Turning back to FIG. 8, the first selector circuit 802 receives min_{1—}l(0), min_{2—}l(0), min_{1—}r(0) and min_{2—}r(0) at inputs 810, 812, 814 and 816, with the selection controlled by idx_l(0), idx_r(0) and circ_idx at inputs 820, 822 and 824, yielding sel[0] at output 826. The second selector circuit 804 receives min_{1—}l(1), min_{2—}l(1), min_{1—}r(1) and min_{2—}r(1) at inputs 830, 832, 834 and 836, with the selection controlled by idx_l(1), idx_r(1) and circ_idx at inputs 840, 842 and 844, yielding sel[1] at output 846. The third selector circuit 806 receives min_{1—}l(2), min_{2—}l(2), min_{1—}r(2) and min_{2—}r(2) at inputs 850, 852, 854 and 856, with the selection controlled by idx_l(2), idx_r(2) and circ_idx at inputs 860, 862 and 864, yielding sel[2] at output 866.

The R values 870, 872 and 874 are generated by the select network 800 according to equations 3-5 based on the sel[k] values 826, 846 and 866. The sel[1] value 846 and sel[2] value 866 are added in adder 876 to yield sum output 880. A minimum selector circuit 882 yields as R[0] output 870 the lesser of sel[0] value 826 and sum output 880. The sel[0] value 826 and sel[2] value 866 are added in adder 884 to yield sum output 886. A minimum selector circuit 888 yields as R[1] output 872 the lesser of sel[1] value 846 and sum output 886. The sel[0] value 826 and sel[1] value 846 are added in adder 890 to yield sum output 892. A minimum selector circuit 894 yields as R[2] output 874 the lesser of sel[2] value 866 and sum output 892.

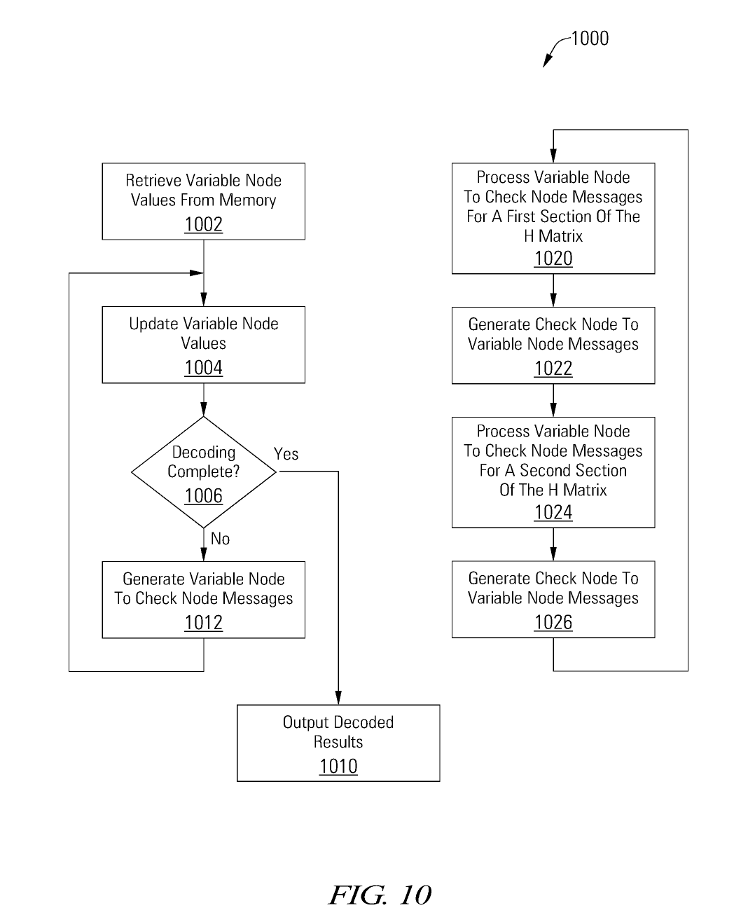

Turning now to FIG. 10, a flow diagram 1000 depicts a method for decoding data in a multi-section non-binary LDPC decoder in accordance with some embodiments of the present inventions. The method of FIG. 10, or variations thereof, may be performed in data decoding circuits such as those illustrated in FIGS. 4-9. Following flow diagram 1000, variable node values are retrieved from memory. (Block 1002) The initial variable node values may be stored in memory as they are received at an input channel (e.g., 402). Variable node values are updated. (Block 1004) For example, in a min-sum based LDPC decoder such as that disclosed in FIG. 4, variable node values may be updated in a adder/subtractor array 410. During the first decoding iteration, before C2V message vectors 412 are prepared, the variable node values may be the initial data stored in the memory 404. Once C2V message vectors 412 are available, the updating may include modifying the variable node values based on the values in C2V message vectors 412, for example by adding and subtracting the LLR values in the C2V message vectors 412 from the variable node values. A determination is made as to whether decoding is complete in the LDPC decoder. (Block 1004) Decoding may be complete, for example, if the variable node values have converged and are no longer changed by C2V message vectors 412. Decoding may also be complete, for example, if a limit on the number of local decoding iterations to be performed has been reached. If decoding is complete, the decoded results are output. (Block 1010) If not, V2C messages are generated. (Block 1012) In some embodiments, the V2C messages are data packets that are transmitted between processors or other circuit elements. In other embodiments, the V2C messages comprise data that is stored in a shared memory that is accessible by variable node processing circuitry and by check node processing circuitry. V2C messages may be generated each time C2V messages are generated, which may be multiple times per local decoding iteration, or once per local decoding iteration.

Check node processing functions, shown in blocks 1020-1026, may be performed partly or fully in parallel with the variable node processing functions of blocks 1004 and 1012, or can be done at different times. In the check node processing, V2C messages are processed for a first section of an H matrix. (Block 1020) In the example min-sum based LDPC decoder, this includes identifying the lowest and next lowest LLR values for the first section of an H matrix. C2V messages are generated. (Block 1022) In some embodiments, there is an update delay period between the time at which block 1020 completes and block 1022 is started. V2C messages are processed for a second section of the H matrix. (Block 1024) C2V messages are generated. (Block 1024) Again, there may be an update period between the completion of block 1024 and the start of block 1026. The C2V messages generated in blocks 1022 and 1026 are based on some embodiments on the results of both blocks 1020 and 1024, with the results from blocks 1020 and 1024 alternatingly having the most recently updated values.

In some embodiments, the C2V messages are generated in blocks 1022 and 1026 according to Equations 1-6. The index of the current working column in the H matrix is compared with the column index of the lowest LLR value for the section of the H matrix being processed to yield an indication of whether the lowest LLR value is from the variable node at the current working column. If not, the lowest LLR value is selected as the lowest extrinsic LLR value for that section of the H matrix. If so, the next lowest LLR value is selected as the lowest extrinsic LLR value for that section of the H matrix. The lesser of the lowest extrinsic LLR value for that section of the H matrix and of the lowest LLR value for a reminder of the H matrix is selected as the lowest extrinsic LLR value for the H matrix. The LLR values in the C2V messages are calculated based on the extrinsic LLR value for the H matrix. The hard decision in the C2V messages are based on combining the parity symbol for each section of the H matrix with the hard decision in the previous V2C message in an XOR operation.

The multi-section non-binary LDPC decoder disclosed herein enhances decoding performance, particularly when decoding iterations are limited. Bit error performance by performing check node updates during local decoding iterations.

Low Density Parity Check (LDPC) technology is applicable to transmission of information over virtually any channel or storage of information on virtually any media. Transmission applications include, but are not limited to, optical fiber, radio frequency channels, wired or wireless local area networks, digital subscriber line technologies, wireless cellular, Ethernet over any medium such as copper or optical fiber, cable channels such as cable television, and Earth-satellite communications. Storage applications include, but are not limited to, hard disk drives, compact disks, digital video disks, magnetic tapes and memory devices such as DRAM, NAND flash, NOR flash, other non-volatile memories and solid state drives.

Although the multi-section non-binary LDPC decoder disclosed herein is not limited to any particular application, several examples of applications are presented in FIGS. 11 and 12 that benefit from embodiments of the present inventions. Turning to FIG. 11, a storage system 1100 is illustrated as an example application of a multi-section non-binary LDPC decoder in accordance with some embodiments of the present inventions. The storage system 1100 includes a read channel circuit 1102 with a multi-section non-binary LDPC decoder in accordance with some embodiments of the present inventions. Storage system 1100 may be, for example, a hard disk drive. Storage system 1100 also includes a preamplifier 1104, an interface controller 1106, a hard disk controller 1110, a motor controller 1112, a spindle motor 1114, a disk platter 1116, and a read/write head assembly 1120. Interface controller 1106 controls addressing and timing of data to/from disk platter 1116. The data on disk platter 1116 consists of groups of magnetic signals that may be detected by read/write head assembly 1120 when the assembly is properly positioned over disk platter 1116. In one embodiment, disk platter 1116 includes magnetic signals recorded in accordance with either a longitudinal or a perpendicular recording scheme.

In a typical read operation, read/write head assembly 1120 is accurately positioned by motor controller 1112 over a desired data track on disk platter 1116. Motor controller 1112 both positions read/write head assembly 1120 in relation to disk platter 1116 and drives spindle motor 1114 by moving read/write head assembly 1120 to the proper data track on disk platter 1116 under the direction of hard disk controller 1110. Spindle motor 1114 spins disk platter 1116 at a determined spin rate (RPMs). Once read/write head assembly 1120 is positioned adjacent the proper data track, magnetic signals representing data on disk platter 1116 are sensed by read/write head assembly 1120 as disk platter 1116 is rotated by spindle motor 1114. The sensed magnetic signals are provided as a continuous, minute analog signal representative of the magnetic data on disk platter 1116. This minute analog signal is transferred from read/write head assembly 1120 to read channel circuit 1102 via preamplifier 1104. Preamplifier 1104 is operable to amplify the minute analog signals accessed from disk platter 1116. In turn, read channel circuit 1102 decodes and digitizes the received analog signal to recreate the information originally written to disk platter 1116. This data is provided as read data 1122 to a receiving circuit. As part of decoding the received information, read channel circuit 1102 processes the received signal using a multi-section non-binary LDPC decoder. Such a multi-section non-binary LDPC decoder may be implemented consistent with that disclosed above in relation to FIGS. 4-9. In some cases, the LDPC decoding may be performed consistent with the flow diagram disclosed above in relation to FIG. 10. A write operation is substantially the opposite of the preceding read operation with write data 1124 being provided to read channel circuit 1102. This data is then encoded and written to disk platter 1116.

It should be noted that storage system 1100 may be integrated into a larger storage system such as, for example, a RAID (redundant array of inexpensive disks or redundant array of independent disks) based storage system. Such a RAID storage system increases stability and reliability through redundancy, combining multiple disks as a logical unit. Data may be spread across a number of disks included in the RAID storage system according to a variety of algorithms and accessed by an operating system as if it were a single disk. For example, data may be mirrored to multiple disks in the RAID storage system, or may be sliced and distributed across multiple disks in a number of techniques. If a small number of disks in the RAID storage system fail or become unavailable, error correction techniques may be used to recreate the missing data based on the remaining portions of the data from the other disks in the RAID storage system. The disks in the RAID storage system may be, but are not limited to, individual storage systems such storage system 700, and may be located in close proximity to each other or distributed more widely for increased security. In a write operation, write data is provided to a controller, which stores the write data across the disks, for example by mirroring or by striping the write data. In a read operation, the controller retrieves the data from the disks. The controller then yields the resulting read data as if the RAID storage system were a single disk.

Turning to FIG. 12, a wireless communication system 1200 or data transmission device including a receiver 1204 with a multi-section non-binary LDPC decoder is shown in accordance with some embodiments of the present invention. Communication system 1200 includes a transmitter 1202 that is operable to transmit encoded information via a transfer medium 1206 as is known in the art. The encoded data is received from transfer medium 1206 by receiver 1204. Receiver 1204 incorporates a multi-section non-binary LDPC decoder. Such a multi-section non-binary LDPC decoder may be implemented consistent with that described above in relation to FIGS. 4-9. In some cases, the LDPC decoding may be done consistent with the flow diagram discussed above in relation to FIG. 10.

It should be noted that the various blocks discussed in the above application may be implemented in integrated circuits along with other functionality. Such integrated circuits may include all of the functions of a given block, system or circuit, or a portion of the functions of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware. In some such cases, the entire system, block or circuit may be implemented using its software or firmware equivalent. In other cases, the one part of a given system, block or circuit may be implemented in software or firmware, while other parts are implemented in hardware.

In conclusion, the present invention provides novel systems, devices, methods and arrangements for decoding data in a multi-section non-binary LDPC decoder. While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

What is claimed is:

1. An apparatus for low density parity check data decoding comprising:
a variable node processor operable to perform variable node updates based at least in part on check node to variable node messages and to generate variable node to check node messages; and
a check node processor operable to process the variable node to check node messages in groups across each of a plurality of sections of an H matrix and to generate the check node to variable node messages.

2. The apparatus of claim 1, wherein each of the groups corresponds with one of the plurality of sections of the H matrix, and wherein check node processor is operable to generate the check node to variable node messages each time one of the groups has been processed.

3. The apparatus of claim 1, wherein the check node to variable node messages are based in part on the most recently processed group of the variable node to check node messages and in part on a remainder of the groups that were processed before the most recently processed group.

4. The apparatus of claim 1, wherein the check node processor is operable to generate the check node to variable node messages multiple times during a single local decoding iteration.

5. The apparatus of claim 1, wherein the check node processor is operable to perform min-sum based low density parity checking of the variable node to check node messages.

6. The apparatus of claim 5, wherein the processing of variable node to check node messages in groups comprises finding lowest likelihood values, next lowest likelihood values, and index of the lowest likelihood values across each of the groups.

7. The apparatus of claim 6, wherein the check node processor is operable to generate the check node to variable node messages by comparing an index of the lowest likelihood value in the group currently being processed with a current working column index in the H matrix and to select that lowest likelihood value as the lowest extrinsic likelihood value for the group currently being processed when the index is equal to the current working column index and to select the next lowest likelihood value when not equal.

8. The apparatus of claim 7, wherein the check node processor is further operable to generate the check node to variable node messages by selecting a lesser of the lowest extrinsic likelihood value for the group currently being processed and of a lowest likelihood value for a reminder of the H matrix as a lowest extrinsic likelihood value for the H matrix, and to calculate likelihood values in the check node to variable node messages based on the lowest extrinsic likelihood value for the H matrix.

9. The apparatus of claim 5, wherein the check node processor is operable to generate the check node to variable node messages by calculating a hard decision in the check node to variable node messages by combining a parity symbol for each of the groups with a hard decision in the variable node to check node messages in an XOR operation.

10. The apparatus of claim 1, wherein the apparatus is implemented as an integrated circuit.

11. The apparatus of claim 1, wherein the apparatus is incorporated in a storage device.

12. The apparatus of claim 11, wherein the storage device comprises:
a storage medium maintaining a data set; and
a read/write head assembly operable to sense the data set on the storage medium and to provide an analog output corresponding to the data set, wherein the variable node processor is operable to receive a signal derived from the analog output.

13. The apparatus of claim 11, wherein the storage device comprises a redundant array of independent disks.

14. The apparatus of claim 1, wherein the apparatus is incorporated in a transmission system.

15. A method for decoding non-binary low density parity check encoded data, the method comprising:
generating variable node to check node messages in a low density parity check decoder; and
process the variable node to check node messages in groups across each of a plurality of sections of an H matrix in the low density parity check decoder;
generating check node to variable node messages multiple times during a single local decoding iteration in the low density parity check decoder; and
updating variable node values based on the check node to variable node messages.

16. The method of claim 15, wherein the check node to variable node messages are generated each time the variable node to check node messages are processed for one of the sections of the H matrix.

17. The method of claim 15, wherein the check node to variable node messages are generated based on a lowest likelihood value, a column index of the lowest likelihood value, and a next lowest likelihood value in the variable node to check node messages for one of the sections of the H matrix most recently processed.

18. The method of claim 17, wherein the check node to variable node messages are generated based also on a lowest likelihood value in the variable node to check node messages for the sections of the H matrix other than that most recently processed.

19. The method of claim 15, wherein the variable node values are updated each time the check node to variable node messages are generated.

20. A storage system comprising:
a storage medium maintaining a data set;
a read/write head assembly operable to sense the data set on the storage medium and to provide an analog output corresponding to the data set;
an analog to digital converter operable to sample a continuous signal to yield a digital output; and
a low density parity check decoder operable to decode the digital output comprising:
a variable node processor operable to perform variable node updates based at least in part on the digital output and on check node to variable node messages and to generate variable node to check node messages; and
a check node processor operable to process the variable node to check node messages in groups across each of a plurality of sections of an H matrix and to generate the check node to variable node messages.
